(19) United States
(12) Patent Application Publication
(10) Pub. No.: US 2012/0121952 A1
(43) Pub. Date: May 17, 2012

(54) BATTERY STATUS DETECTING DEVICE AND BATTERY PACK WHERE THE BATTERY STATUS DETECTING DEVICE IS PROVIDED

(76) Inventors: Yoshihide Majima, Tokyo (JP); Kazuhiko Takeno, Kanagawa (JP); Yasuyuki Kanai, Tokyo (JP); Haruo Uemura, Kumamoto (JP)

(21) Appl. No.: 13/062,555

(22) PCT Filed: Aug. 28, 2009
(86) PCT No.: PCT/JP2009/065067

§ 371 Date: Mar. 31, 2011

(30) Foreign Application Priority Data
Sep. 11, 2008 (JP) 2008-233727

(51) Int. Cl. H01M 10/48; G01R 31/36

(52) U.S. Cl. 429/90; 702/63

(57) ABSTRACT

A battery status detecting device, the battery status detecting device being configured to detect a status of a rechargeable battery which powers an electronic device, the battery status detecting device includes a capacity degradation rate calculating part configured to calculate a capacity degradation rate of the rechargeable battery; an internal resistance value calculating part configured to calculate an internal resistance value of the rechargeable battery; a determining part configured to determine necessity of exchange of the rechargeable battery based on the capacity degradation rate calculated by the capacity degradation rate calculating part and the internal resistance value calculated by the internal resistance value calculating part; and an outputting part configured to output a signal corresponding to a determination result of the determining part, wherein the determining part determines that the exchange of the rechargeable battery is necessary in a case where one of or both of the capacity degradation rate calculated by the capacity degradation rate calculating part and the internal resistance value calculated by the internal resistance value calculating part reach a value requiring the exchange of the rechargeable battery.

### TECHNICAL FIELD

The present invention generally relates to battery status detecting devices and battery packs where the battery status detecting devices are provided. More specifically, the present invention relates to a battery status detecting device, the battery status detecting device being configured to detect a status of a rechargeable battery which powers an electronic device, and a battery pack where the battery status detecting device is provided.

### BACKGROUND ART

It is expected that, due to progress of degradation of a rechargeable battery, an operating time of an electronic device where a power supply is applied from the rechargeable battery may be shortened or a rate of generation of problems, such as an internal short circuit, may be increased. A main reason of the degradation may be increasing of an internal resistance value of the rechargeable battery. Because of this, a degradation state of the rechargeable battery is determined by calculating the internal resistance value based on a detected value of a voltage or an electric current of the rechargeable battery.

On the other hand, in Patent Document 1 mentioned below, an LED whereby encouragement of battery exchange is indicated based on the value of an estimation capacity ratio C/C₀ (C: estimation capacity of lithium battery, and C₀: nominal capacity of lithium battery) calculated as a result of determination of degradation has been suggested. Here, for example, red indicates battery exchange, yellow indicates battery exchange shortly; and green indicates no necessity of battery exchange.
[Patent Document 1] Japanese Patent Application Laid-Open Publication No. 2001-289924

### DISCLOSURE OF THE INVENTION

### Problems to be Solved by the Invention

However, even if the estimation capacity ratio discussed in Patent Document 1 is replaced with the internal resistance value and information of necessity of the rechargeable battery exchange should be provided to the user, the following problem exists. In other words, changing properties of the internal resistance value are different between a case where degradation is based on repeating of charge and discharge and a case where degradation is based on keeping the battery in a high temperature status. Therefore, depending on the reason of the degradation of the rechargeable battery, it may not be possible to securely provide information of the necessity of the rechargeable battery exchange to the user.

### Means for Solving Problems

Accordingly, embodiments of the present invention may provide a novel and useful battery status detecting device and battery pack where the battery status detecting device is provided, solving one or more of the problems discussed above.

More specifically, the embodiments of the present invention may provide a battery status detecting device configured to securely provide information of necessity of the rechargeable battery exchange to the user regardless of the reason of the degradation of the rechargeable battery, and a battery pack where the battery status detecting device is provided.

One aspect of the present invention may be to provide a battery status detecting device, the battery status detecting device being configured to detect a status of a rechargeable battery which powers an electronic device, the battery status detecting device including: a capacity degradation rate calculating part configured to calculate a capacity degradation rate of the rechargeable battery; an internal resistance value calculating part configured to calculate an internal resistance value of the rechargeable battery; a determining part configured to determine necessity of exchange of the rechargeable battery based on the capacity degradation rate calculated by the capacity degradation rate calculating part and the internal resistance value calculated by the internal resistance value calculating part; and an outputting part configured to output a signal corresponding to a determination result of the determining part, wherein the determining part determines that the exchange of the rechargeable battery is necessary in a case where one of or both of the capacity degradation rate calculated by the capacity degradation rate calculating part and the internal resistance value calculated by the internal resistance value calculating part reach a value requiring the exchange of the rechargeable battery.

Another aspect of the present invention may be to provide a battery status detecting device, the battery status detecting device being configured to detect a status of a rechargeable battery which powers an electronic device, the battery status detecting device including: a capacity degradation rate calculating part configured to calculate a capacity degradation rate of the rechargeable battery; an internal resistance value calculating part configured to calculate an internal resistance value of the rechargeable battery; a determining part configured to determine necessity of exchange of the rechargeable battery based on the capacity degradation rate calculated by the capacity degradation rate calculating part and the internal resistance value calculated by the internal resistance value calculating part; and an outputting part configured to output a signal corresponding to a determination result of the determining part, wherein the determining part calculates a degradation state amount, the degradation state amount indicating a degradation state of the rechargeable battery, the degradation state amount being where a capacity degradation rate calculated by the capacity degradation rate calculating part and an internal resistance value calculated by the internal resistance value calculating part are reflected as an element for defining the degradation state of the rechargeable battery, so as to determine that the exchange of the rechargeable battery is necessary in a case where the calculated degradation state amount reaches a value requiring the exchange of the rechargeable battery.

Another aspect of the present invention may be to provide a battery pack, including: the above-mentioned battery status detecting device; and a rechargeable battery, wherein the battery status detecting device and the rechargeable battery are provided in the battery pack.

Additional objects and advantages of the embodiments will be set forth in part in the description which follows, and in part will be obvious from the description, or may be learned by practice of the invention. The object and advantages of the invention will be realized and attained by means of the elements and combinations particularly pointed out in the appended claims. It is to be understood that both the foregoing general description and the following detailed description are exemplary and explanatory and are not restrictive of the invention as claimed.

### Effect of the Invention

According to the embodiment of the present invention, it is possible to provide a battery status detecting device configured to securely provide information of necessity of the rechargeable battery exchange to the user regardless of the reason of the degradation of the rechargeable battery, and a battery pack where the battery status detecting device is provided.

### BRIEF DESCRIPTION OF DRAWINGS

FIG. 1 is an entire structural view of an intelligent battery pack 100A of an embodiment of a battery pack of the present invention;

FIG. 2 is a graph showing properties of “open-circuit voltage-charging rate” at 25° C.;

FIG. 3 is a calculating flow of an internal resistance value of a managing system of the battery pack 100A;

FIG. 4 is a sequential diagram of charging detection;

FIG. 5 is a graph showing a measurement result of relationships between the internal resistance value and a remaining capacity due to difference of degradation reasons and degradation state of the lithium ion battery (changing impedance properties at 25° C. after charging starts); and

FIG. 6 shows a display example of a displaying part 310.

### MODE FOR CARRYING OUT THE INVENTION

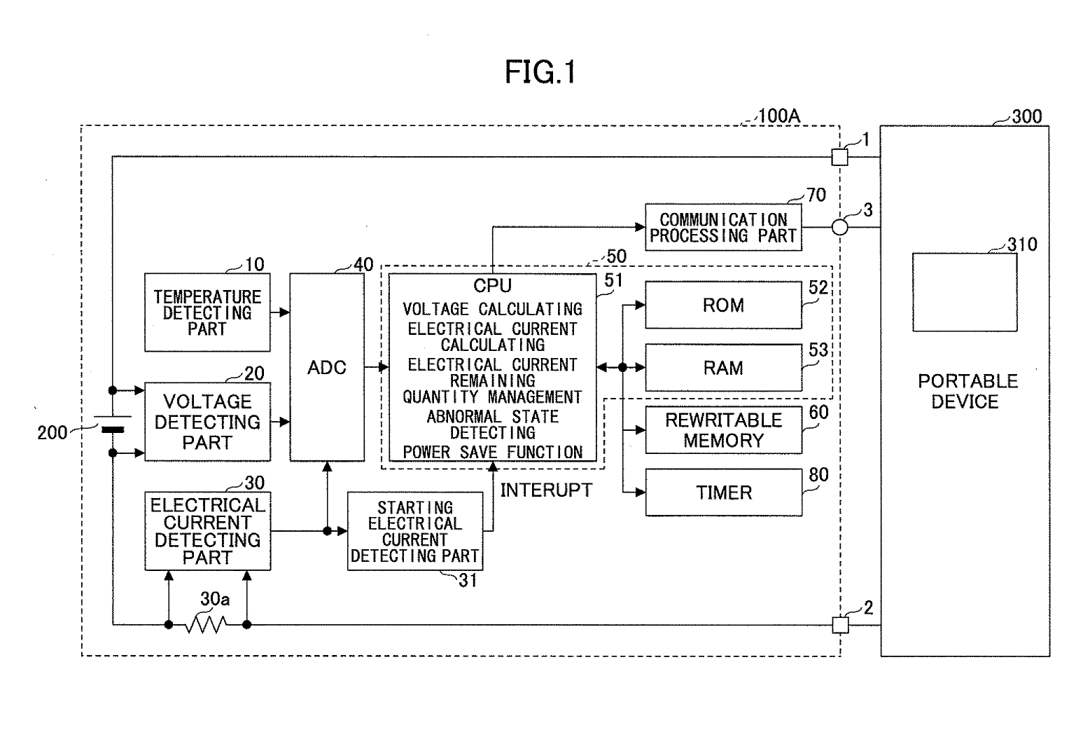

A description is given below, with reference to FIG. 1 through FIG. 6 of embodiments of the present invention.

FIG. 1 is an entire structural view of an intelligent battery pack 100A of an embodiment of a battery pack of the present invention. A battery status detecting device, as a managing system configured to manage a battery state, is provided in the battery pack 100A. The battery status detecting device includes a temperature detecting part 10, a voltage detecting part 20, an electrical current detecting part 30, an AD converter (hereinafter “ADC”) 40, a calculating processing part 50, a memory 60, a communication processing part 70, a timer part 80, and a starting electrical current detecting part 31.

The temperature detecting part 10 is configured to detect a temperature of a periphery of a rechargeable battery 200 such as a lithium ion battery, a nickel hydrogen battery, or an electrical double layer capacitor. The voltage detecting part 20 is configured to detect a voltage of the rechargeable battery 200. The electrical current detecting part 30 is configured to detect charge and discharge electrical currents of the rechargeable battery 200. The ADC 40 is configured to convert analog values which are output from the detecting parts and which indicate detecting result, into digital values.

The calculating processing part 50 is configured to perform calculating processes such as electrical current accumulation, capacity correction, and dischargeable capacity. The calculating processing part 50 may be, for example, a microcomputer including a CPU 51, a ROM 52, a RAM 53, and others. The memory 60 is configured to store characteristic data for specifying characteristics of each of components of the rechargeable battery 200 or the battery pack 100A used for the calculating processes performed by the calculating processing part 50 and information peculiar to the battery pack 100A. The memory 60 may be a storing device such as an EEPROM or a flash memory.

The communication processing part 70 is configured to transfer battery information such as a battery state of the rechargeable battery 200 to a portable device 300 whose electric power supply is the rechargeable battery 200. The communication processing part 70 may be, for example, an IC for communication. The timer part 80 is configured to manage the time. The starting electrical current detecting part 31 is configured to detect the starting electrical current of the portable device 300 based on the detecting result of the electrical current detecting part 30.

A part or entirety of components of the battery status detecting device may be formed by an integrated circuit. In addition, the portable device 300 includes a display part 310, such as a display, as an information providing part configured to provide the information to the user.

The battery pack 100A is a module component where the rechargeable battery 200 and a managing system configured to manage the battery state of the rechargeable battery 200 are combined. The battery pack 100A is connected to the portable device 300 via electrode terminals (a positive electrode terminal 1 and a negative electrode terminal 2) and a communication terminal 3. The positive electrode terminal 1 is electrically connected to a positive pole of the rechargeable battery 200 via a current-carrying path. The negative electrode terminal 2 is electrically connected to a negative pole of the rechargeable battery 200 via a current-carrying path. The communication terminal 3 is connected to the communication processing part 70. The communication processing part 70 is an outputting part configured to output transferring information based on the result of the processing of the calculating processing part 50 to the portable device 300.

The portable device 300 is an electronic device which can be carried by a human. More specifically, the portable device 300 may be, for example, a portable phone, an information terminal device such as a PDA or a mobile personal computer, a camera, a game device, a music or video player, or the like. The portable pack 100A may be provided in or externally provided to the portable device 300. The portable device 300 is configured to perform an operation corresponding to the battery information based on the battery information such as the battery state obtained from the communication processing part 70. The portable device 300 displays, for example, the battery state information, for example, residual quantity information, degradation information, and exchange timing information of the rechargeable battery 200, on a display part such as a display part 310. The portable device 300 changes an operation mode of the portable device 300 based on the battery state information. For example, the portable device 300 changes from a normal consumption of electric power mode to a low consumption of electric power mode.

The rechargeable battery 200 is a power supply of the portable device 300. The rechargeable battery 200 is a power supply of the ADC 40, the calculating processing part 50, the communication processing part 70, and the timer 80. In addition, the temperature detecting part 10, the voltage detecting part 20, the electrical current detecting part 30, and the starting electrical current detecting part 31 may require, depending on circuit structures thereof, an electrical power supply from the rechargeable battery 200. Even if the electrical power supply from the rechargeable battery 200 is shut off, contents stored in the memory 60 are maintained. The temperature detecting part 10, the voltage detecting part 20, the electrical current detecting part 30, the ADC 40, and the calculating processing part 50 function as status detecting parts configured to detect the battery status of the rechargeable battery 200.

The temperature detecting part 10 is configured to detect the temperature of the periphery of the rechargeable battery 200 so as to convert the detected temperature to a voltage which can be input to the ADC 40 and output it to the ADC 40. A digital value of the battery temperature indicating the temperature of the periphery of the rechargeable battery 200, converted by the ADC 40, is transmitted to the calculating processing part 50 so as to be used as a parameter for calculating processing. In addition, the digital value of the battery temperature is converted to units predetermined in advance by the calculating processing part 50 so as to be output to the portable device 300 via the communication processing part 70 as battery status information indicating the battery status of the rechargeable battery 200. Since the rechargeable battery 200 is provided in the battery pack 100A, the temperature detecting part 10 may detect the temperature of the rechargeable battery 200 itself or the temperature of the periphery of the rechargeable battery 200 as a temperature of the battery pack 100A or components of the battery pack 100A.

The voltage detecting part 20 is configured to detect the voltage of the rechargeable battery 200 so as to convert the detected voltage to a voltage which can be input to the ADC 40 and output it to the ADC 40. A digital value of the battery voltage indicating the voltage of the rechargeable battery 200, converted by the ADC 40, is transmitted to the calculating processing part 50 so as to be used as a parameter for calculating processing. In addition, the digital value of the battery voltage is converted to units predetermined in advance by the calculating processing part 50 so as to be output to the portable device 300 via the communication processing part 70 as battery status information indicating the battery status of the rechargeable battery 200.

The electrical current detecting part 30 is configured to detect a charge and discharge electrical current of the rechargeable battery 200 so as to convert the detected electrical current to a voltage which can be input to the ADC 40 and output it to the ADC 40. The electrical current detecting part 30 includes an electrical current detecting resistor 30a connected to the rechargeable battery 200 in series and an operational amplifier. The operational amplifier is configured to amplify a voltage generated between both ends of the electrical current detecting resistor 30a. The electrical current detecting part 30 is configured to convert the charge and discharge electrical current to the voltage by the electrical current detecting resistor 30a and the operational amplifier. The operational amplifier may be provided in the ADC 40. A digital value, converted by the ADC 40, indicating the charge and discharge electrical current of the rechargeable battery 200 is transmitted to the calculating processing part 50 so as to be used as a parameter for calculating processing. In addition, the digital value of the battery electrical current is converted to units predetermined in advance by the calculating processing part 50 so as to be output to the portable device 300 via the communication processing part 70 as battery status information indicating the battery status of the rechargeable battery 200.

The calculating processing part 50 is configured to compute the remaining capacity of the rechargeable battery 200. Although a proper method may be optionally used as a calculating method of the remaining capacity, the following method is one of examples of the calculating method of the remaining capacity.

The calculating processing part 50 is configured to integrate an electrical current value, the electrical current value being detected by the electrical current detecting part 30 in a charging or discharging state of the rechargeable battery 200 (for example, a state where an electrical current having a value equal to or greater than a designated value is consumed due to operations of the portable device 300). Because of this, as an electrical quantity which can be charged or discharged at the rechargeable battery 200, a present electrical quantity (remaining capacity) stored in the rechargeable battery 200 can be calculated. With respect to calculating the remaining capacity of the rechargeable battery 200, the following idea is suggested in Japanese Laid-Open Patent Application Publication No. 2004-226393, for example. That is, in a case where conditions such as the temperature or the electrical current are changed in the charge and discharge of the rechargeable battery 200, efficiency of charge and discharge is not changed. An electrical quantity, which cannot be charged or discharged for a while based on each of the charge and discharge conditions, exists and is changed. According to this idea, it is not necessary to perform a correcting process of the efficiency of charge and discharge.

In a case where a temperature-dependent circuit part which depends on a temperature of components of the battery pack 100A is provided, the calculating processing part 50 may detect a temperature of the periphery by the temperature detecting part 10 so that a charge and discharge electrical current value of the rechargeable battery 200 converted by the ADC 40 may be corrected based on “charge and discharge electrical current-temperature” characteristics. The “charge and discharge electrical current-temperature” characteristics are indicated by a correction table or a correction function. Data in the correction table or coefficients of the correction function are stored in the memory 60 as characteristics data. The calculating process part 50, following the correction table or correction function where characteristics data read from the memory 60 are reflected, is configured to correct the charge and discharge electrical current value based on the temperature measured by the temperature detecting part 10.

On the other hand, if the charge and discharge of the rechargeable battery 200 stops (for example, the operation of the portable device 300 stops or is in stand-by state), the charge and discharge electrical current value becomes smaller that that in the charge state or the discharge state. As a result of this, if a state where a lot of errors are contained in the measurement by the electrical current detecting part 30 or the ADC 40 or a state where measurement by the electrical current detecting part 30 or the ADC 40 cannot be made continues for a certain period of time due to a reason such as resolution, the error in the process of the electrical current integration is integrated due to calculation of the remaining capacity and therefore precision of the calculation of the remaining capacity is lost. In order to prevent this situation, the calculating processing part 50 may stop an integration process of the electrical current values or may store consumption electrical current values of the portable device 300 measured in advance and may integrate the values.

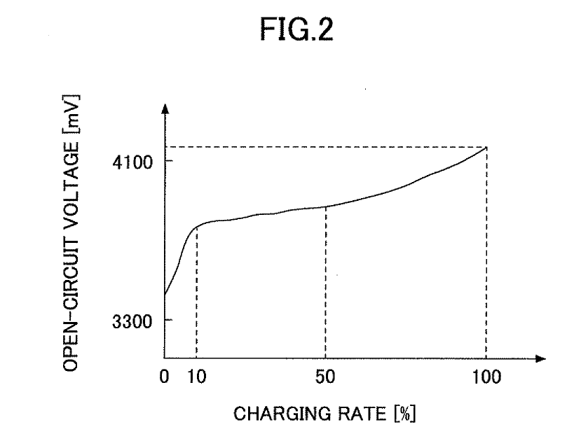

In order to improve the calculating precision of the remaining capacity, the efficiency of charge and discharge, or the like, if the stopping state of the portable device 300 continues for a designated time, the calculating processing part 50 periodically measures the voltage (open-circuit voltage) of the rechargeable battery 200 so that the charging rate is calculated and corrected based on “open-circuit voltage-charging rate” characteristics (see FIG. 2). The open-circuit voltage is a voltage between bipolar electrodes measured by opening the stable bipolar electrodes of the rechargeable battery 200 or in a high impedance condition. The charging rate, indicated as “%”, is a proportion of the remaining capacity of the rechargeable battery 200 when a full charge capacity of the rechargeable battery 200 is regarded as 100. “Open-circuit voltage-charging rate” characteristics are expressed by the correction table or the correction function. The data in the correction table or coefficients of the correction function are stored in the memory 60 as characteristics data. The calculating processing part 50, following the correction table or correction function where characteristics data read from the memory 60 are reflected, is configured to calculate and correct the charge and discharge electrical current value based on the temperature measured by the voltage detecting part 20.

In addition, in a case where temperature characteristics exist in the open-circuit voltage of the rechargeable battery 200, the calculating processing part 50 may perform designated temperature correction on the open-circuit voltage. For example, the calculating processing part 50 may detect a temperature of the periphery by the temperature detecting part 10 so that the open-circuit voltage of the rechargeable battery 200 converted by the ADC 40 may be corrected based on “charge and discharge electrical current-temperature” characteristics. The “charge and discharge electrical current-temperature” characteristics are indicated by a correction table or a correction function. The data in the correction table or coefficients of the correction function are stored in the memory 60 as characteristics data. The calculating processing part 50, following the correction table or correction function where characteristics data read from the memory 60 are reflected, is configured to correct the charge and open-circuit voltage based on the temperature measured by the temperature detecting part 10.

As discussed above, the calculating processing part 50 can compute the charging rate of the rechargeable battery 200. However, since the remaining capacity of the rechargeable battery 200 can be calculated based on the relationship between the full-charge capacity and the charging rate, if the full-charge capacity of the rechargeable battery 200 is not measured or estimated, it is not possible to calculate the remaining capacity of the rechargeable battery 200.

As a method for calculating the full-charge capacity of the rechargeable battery 200, for example, a method for calculating based on the charge quantity of the rechargeable battery 200 or based on the charged quantity may be used. For example, when the full-charge capacity of the rechargeable battery 200 is calculating based on the charged quantity, charging is performed by constant voltage or constant electrical current in a case of the charging other than the pulse charge. Therefore, in this case, compared to a case where the full-charge capacity of the rechargeable battery 200 is calculating based on the charged quantity which may be easily influenced by the consumption electrical current characteristics of the portable device 300, it is possible to precisely measure the charge electrical current. Which method of the above-discussed two kinds of the methods is used may be determined based on the characteristics of the portable device 300. Both or either method can be selected.

Conditions for precisely measuring the full-charge capacity include a case where charging is continuously performed from a state where the remaining capacity is zero to a full-charge state. An electrical current value integrated in this charting term yields a full charge capacity. However, it is rare that such charging occurs. It is normal practice that charging is applied from a state where a certain remaining capacity exists.

Accordingly, the calculating processing part 50, considering the above-mentioned case, calculates the full-charge capacity of the rechargeable battery 200 based on a battery voltage just before the charging is started and a battery voltage after a designated time has passed from when the charging is completed. In other words, the calculating processing part 50 calculates the charged portion just before the charging is started based on the battery voltage and the “open circuit voltage-charging rate” characteristics (see FIG. 2) and calculates the charged portion after the designated time has passed from when the charging is completed based on the battery voltage after the designated time has passed from when the charging is completed and the “open circuit voltage-charging rate” characteristics (see FIG. 2). The calculating processing part 50 calculates the full-charge capacity FCC of the rechargeable battery 200 by the following formula (1).

FCC=Q/{(SOC2−SOC1)/100} (1)

wherein the full-charge capacity is denoted by FCC [mAh];

the charged rate (portion) just before the charging is started is denoted by SOC1 [%]; the charged rate (portion) after the designated time has passed from when the charging is completed is denoted by SOC2 [%]; and the electrical quantity charged in a charging period from when the charging is started to when the charging is completed is denoted by Q [mAh]. If the temperature correction is made for SOC1 or SOC2, a precise value can be calculated. Furthermore, by using the battery voltage after the designated time has passed from when the charging is completed, the battery voltage being more stable than a voltage at the time of the charging is completed is reflected in the calculation so that precision of the result of calculation can be improved.

Accordingly, based on the charging rate and the full-charge capacity calculated above, it is possible to calculate the remaining capacity of the rechargeable battery 200 (remaining capacity=full-charge capacity×charging rate).

In addition, since the full-charge capacity FCC can be calculated, it is possible to estimate a capacity degradation rate SOH [%] of the rechargeable battery 200. The calculating processing part 50 can calculate the capacity degradation rate SOH [%] of the rechargeable battery 200 at an optional timing by using the following formula (2)

SOH=RFCC/AFCC×100 (2)

wherein an initial full-charge capacity is denoted by AFCC; and a full-charge capacity at an optional time is denoted by RFCC. The capacity degradation rate SOH of this embodiment indicates a degree of how much a device is new. As understood via the formula (2), as the value of SOH is smaller, the rechargeable battery is degraded more. In order to show that as the value of SOH is greater, the rechargeable battery is degraded more, the definition of the formula (2) may be changed.

In this embodiment, the calculating processing part 50 calculates an internal resistance value of the rechargeable battery 200.

Although a proper method may be optionally used as a calculating method of the internal resistance value, the following method is one of examples of the calculating method of the internal resistance value.

The calculating processing part 50 detects and calculates an electrical current difference of the charge and discharge electrical current in a unit time including a charge and discharge starting point of the rechargeable battery 200 and a voltage difference of the battery voltage in the same time period as the unit time, so that the internal resistance value of the rechargeable battery 200 is calculated.

That is to say, the internal resistance value just before charging is started is regarded to be equal to the internal resistance value at the time when a designated time passes after charging is started. The internal resistance value Rc of the rechargeable battery 200 is calculated by the following internal resistance value calculating formula (3).

Rc=(V1−V0)/(I1−I0) (3)

wherein the battery voltage just before charging is started is denoted by V0, the charging electrical current just before charging is started is denoted by I0; the battery voltage at the time when a designated time passes after charging is started is denoted by V1; and the charging electrical current at the time when a designated time passes after charging is started is denoted by I1.

A confirmation test was performed in order to confirm a stable calculating result of the internal resistance value was obtained by assigning the electrical current and the voltage detected before or after charging is started to the formula (3). According to the result of the test, even if the charging electrical current is different in a state where degradation compared to the new product has progressed, a stable internal resistance value can be calculated based on the voltage value and the electrical current difference between before and after charging is started.

Accordingly, in a case where after a stopping state where the charging and discharging electrical current value of the rechargeable battery 200 is zero or a minute charging and discharging electrical current flowing to the rechargeable battery 200 is detected for a designated time, and a charging state where a charge and discharge electrical current having a value greater than the electrical current value in the stopping state flows is detected, the internal resistance value of the rechargeable battery 200 may be calculated as follows. That is, the internal resistance value of the rechargeable battery 200 may be calculated by using the formula (3) based on the voltage value and electrical current value of the rechargeable battery 200 in the charging state when a designated time passes from the time when the charging electrical current value greater than the designated value is detected, and the voltage value and electrical current value of the rechargeable battery 200 in the stopping state before the charging electrical current value greater than the designated value is detected. The calculating processing part 50 can determine a minute short-circuit of the rechargeable battery 200 by detecting that the calculated internal resistance value is decreased from an initial value (stored in the memory 60 or the like in advance). The determining information is transmitted to the portable device 30 via the communication processing part 70.

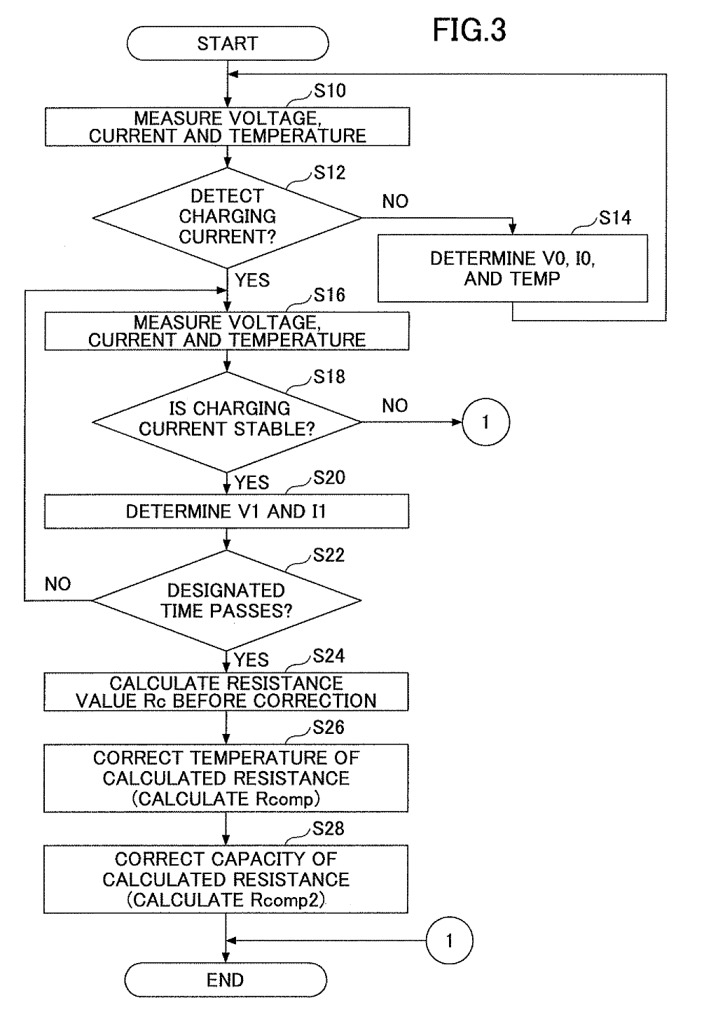

FIG. 3 is a calculating flow of an internal resistance value of a managing system of the battery pack 100A. The managing system where the calculating processing part 50 is a main portion is operated. The calculating processing part 50, after the managing system is initialized, performs temperature measurement by the temperature detecting part 10, voltage measurement by the voltage detecting part 20, and electrical current measurement by the electrical current detecting part 30 (step S10). The calculating processing part 50 detects measured values by these detecting parts with a designated detecting cycle so that data at the same time of the voltage value, the electrical current value, and the temperature value are stored in a memory such as the RAM 53. This detecting cycle may be determined by considering standing-up characteristics of the battery voltage at the time when the rechargeable battery 200 is charged so that the voltage difference and the electrical current difference can be precisely detected between before and after standing up of the battery voltage at the time when the rechargeable battery 200 is charged.

After the stopping state where the charging and discharging electrical current value of the rechargeable battery 200 is zero or a minute charging and discharging electrical current flows to the rechargeable battery 200 is detected for a designated time by the electrical current detecting part 30, the calculating processing part 50 determines whether or not the electrical current detected by the electrical current detecting part 30 is equal to or greater than a positive first electrical current threshold value for determining the start of charging of the rechargeable battery 200 (step S12). If the electrical current detected by the electrical current detecting part 30 at a detecting timing in step S10 is not equal to or greater than the first electrical current threshold value, the calculating processing part 50 determines that the detected voltage, electrical current, and temperature, as detected values V0, I0, and Temp just before charging is started (step S14). After the determination, the process goes to step S10. The values V0, I0, and Temp are updated until the electrical current detected by the electrical current detecting part 30 in step S12 becomes equal to or greater than the first electrical current threshold value.

In a case where the electrical current detected by the electrical current detecting part 30 in step S10 is not equal to or greater than the first electrical current threshold value (absolute value) but is a discharge electrical current value (absolute value) being a designated value equal to or greater than 0, the detected value is not proper for calculating the correct internal resistance value and therefore may be excluded.

On the other hand, in a case where the electrical current detected by the electrical current detecting part 30 in step S10 is equal to or greater than the first electrical current threshold value, the calculating processing part 50 regards in step S12 that the charging to the rechargeable battery 200 is started so as to perform again the temperature measurement by the temperature detecting part 10, the voltage measurement by the voltage detecting part 20, and the electrical current measurement by the electrical current detecting part 30 (step S16). The calculating processing part 50 determines whether or not the electrical current detected by the electrical current detecting part 30 in step S10 is equal to or greater than a designated second electrical current threshold value which is greater than the first electrical current threshold value (step S18). The second electrical current threshold value is a threshold value for determining whether a state is a stable charging state after the charging electrical current charging the rechargeable battery 200 stands up (a charging state where a changing quantity of the charging electrical current is smaller than that in a charging electrical current standing state).

In a case where the electrical current detected by the electrical current detecting part 30 in step S16 is not equal to or greater than the second electrical current threshold value, the charging electrical current after charging is started is not stable and is improper for calculating the internal resistance value. Therefore, the calculating processing part 50 ends this process flow. On the other hand, in a case where the electrical current detected by the electrical current detecting part 30 in step S16 is equal to or greater than the second electrical current threshold value, the charging electrical current is regarded to be stable. The calculating processing part 50 determines the detected voltage and electrical current as detected values V1 and I1 at the time when a designated time passes after charging is started (step 20). In addition, if a designated time does not pass in step S22, after the electrical current value equal to or greater than the first electrical current threshold value is detected, the charging electrical current is regarded as being standing up and the process goes back to step S16. On the other hand, if the designated time passes after the electrical current being equal to or greater than the first electrical current threshold value is detected, the process goes to step S24. In step S24, the calculating processing part 50 follows the formula (3) so as to calculate the internal resistance value R of the rechargeable battery 200.

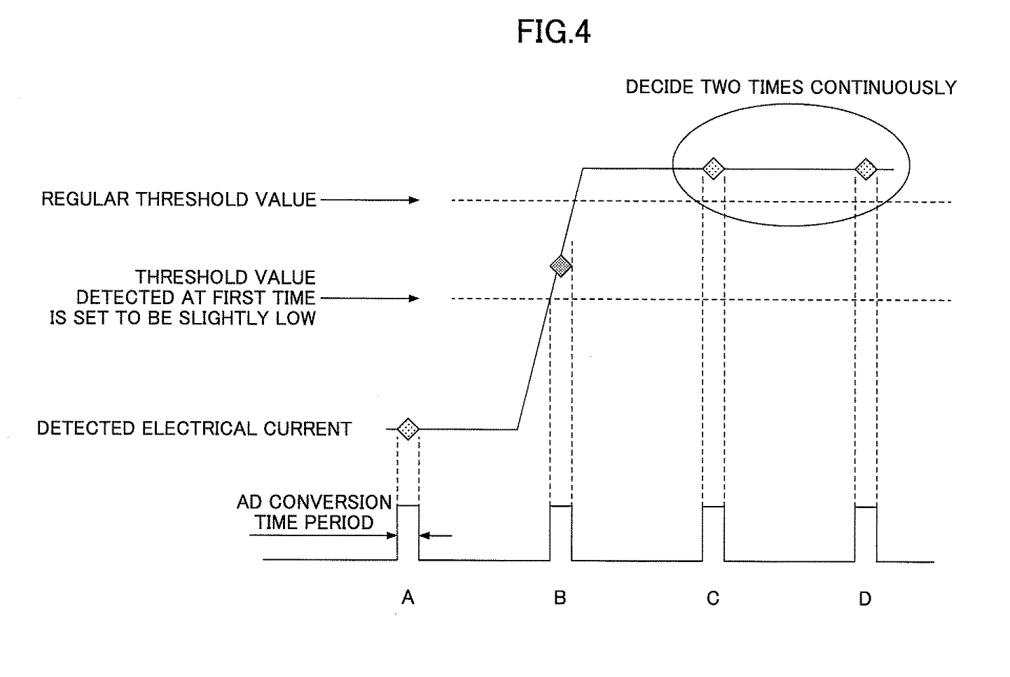

Therefore, the internal resistance value Rc is calculated for every time when the rechargeable battery 200 is charged. As shown in FIG. 4, by setting the first electrical current threshold value for determining start of charging and the second electrical current threshold value greater than the first electrical current threshold value, the charging start time of the rechargeable battery 200 is securely recognized so that the detected value in a stable charging state can be used for calculation of the internal resistance value.

In a case where the portable device 300 is operated so that the electrical current is intermittently consumed (for example, switching between a normal electric power consumption mode and a low consumption electric power mode is intermittent; or the consumption electrical current is periodically 100 mA while the consumption electrical current in a steady state is 1 mA), a standing-up timing is overlapped with a detecting timing of the electrical current I0 before the charge is started or the electrical current I1 after the charge is started, and the calculating error of the internal resistance value becomes larger. However, by considering the operation state of the portable device 300 so as to set two electrical current threshold values and calculate the internal resistance value as discussed above, it is possible to inhibit the calculating error of the internal resistance value. Furthermore, in order to inhibit the calculating error of the internal resistance value, considering the operation state of the portable device 300, for example, an average value of the detected values of plural times, an average value of the detected values of plural times most of which are consistent with each other, or detected values of continuously n-times being consistent with each other may be assigned to the internal resistance value formula.

However, in a case where temperature characteristics depend on a structural part of the rechargeable battery 200 and the battery pack 100A, the internal resistance value Rc has temperature characteristics. For example, as the temperature of the periphery is increased more, the open-circuit voltage of the rechargeable battery 200 becomes smaller. In addition, since the temperature detecting part 10, the voltage detecting part 20, the electrical current detecting part 30, the AD converter 40, and others have analog elements such as a resistor, transistor, or amplifier, the temperature detecting part 10, the voltage detecting part 20, the electrical current detecting part 30, the AD converter 40, and others can be temperature-dependent circuit parts. It is normal practice to design an integrated circuit by considering the temperature dependency of an element in a wafer. However, since unevenness of the manufacturing process or characteristics unevenness in the wafer surface occurs, the manufactured IC has slight temperature characteristics.

Because of this, even if measurement is made at any temperature by using temperature information at the time when the resistance is calculated, corrections are calculated so that the calculated internal resistance values are equal to each other. The calculating processing part 50 corrects the resistance value Rc calculated in step S24 based on the temperature of the periphery so that the first correction resistance value Rcomp is calculated (step S26 shown in FIG. 3).

An optional and proper method may be used as a correcting method using the temperature of the internal resistance. “Internal resistance value-temperature” characteristics are indicated by the correction table or the correction function. The data in the correction table or coefficients of the correction function are stored in the memory 60 as characteristics data. The calculating processing part 50, following the correction table or correction function where characteristics data read from the memory 60 are reflected, can calculate the first correction resistance value Rcomp where the internal resistance value Rc is corrected by the temperature at the measuring time by the temperature detecting part 10.

In addition, since the calculated internal resistance value is changed based on the remaining capacity of the rechargeable battery, the correction calculation is made so that a substantially constant internal resistance value is calculated even if the remaining capacity at the measuring time is different. The calculating processing part 50 calculates the second correction resistance value Rcomp2 by correcting the resistance value Rcomp calculated in step S26 based on the remaining capacity (step S28).

An optional and proper method may be used as a correcting method using the remaining capacity of the internal resistance. “Internal resistance value-remaining capacity” characteristics are indicated by the correction table or the correction function. The data in the correction table or coefficients of the correction function are stored in the memory 60 as characteristics data. The calculating processing part 50, following the correction table or correction function where characteristics data read from the memory 60 are reflected, can calculate the second correction resistance value Rcomp2 where the first correction resistance value Rcomp is corrected by the remaining capacity Q0 before charging is started. As a result if this, it is possible to calculate the internal resistance precisely.

In the meantime, in the rechargeable battery such as a lithium ion battery, the internal resistance value may be increased or the battery capacity (full-charge capacity) is decreased due to repeating of the charge and discharge or keeping the battery at a high temperature. In a case where the battery in this state continues being used, operational time of the portable device is shortened so that frequent charging is required. In addition, if the battery is used for a long period of time, the likelihood of a problem occurring such as an internal short-circuit may be increased. Under this circumstance, in this embodiment as discussed below, threshold values are set to a reduction rate of the full-charge capacity and the internal resistance value in order to provide a proper exchanging timing of the battery to the user of the portable device, and thereby usefulness to the user and safety of the battery can be improved.

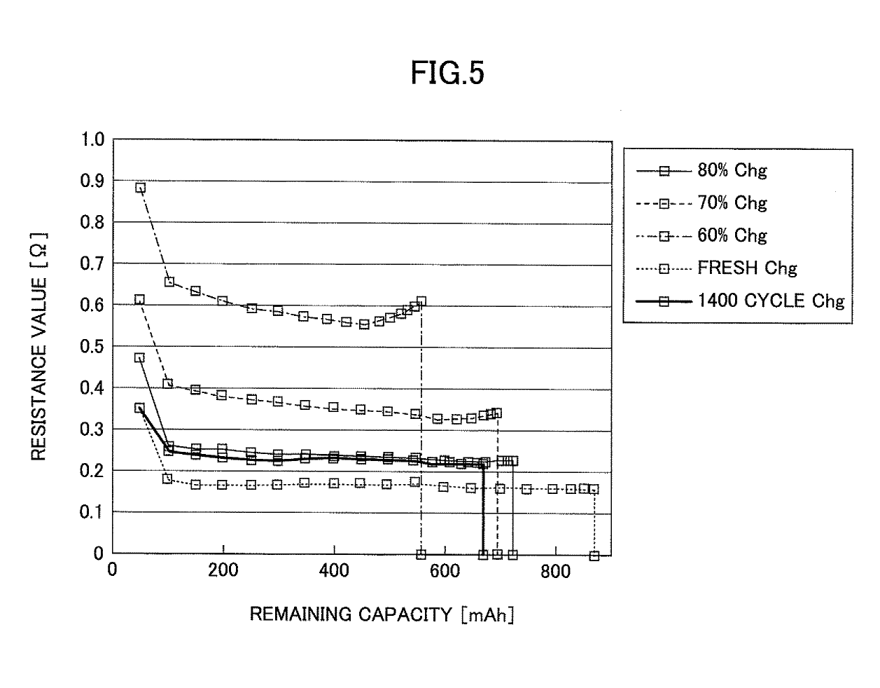

Degradation of the battery is shown as a phenomenon where the use time of the user is reduced. The degradation of the battery is also shown as degradation of electrolytic solution or the electrodes inside the battery. Thus, each of them indicates different characteristics. The degradation due to repeating of charge and discharge is shown as a characteristics change of the electrolytic solution, and, in this case, the internal resistance increases only slightly. On the other hand, continuing degradation due to keeping the battery at high temperature is shown as degradation of the electrodes, and, in this case, increase of the internal resistance value is observed. This is discussed with reference to FIG. 5.

FIG. 5 is a graph showing a measurement result of relationships between the internal resistance value and a remaining capacity due to difference of degradation reasons and degradation state of the lithium ion battery. The internal resistance value and the remaining capacity are measured by the above-discussed method. “80% Chg” indicates a measurement result of a battery where the capacity degradation rate due to continuing degradation is adjusted to 80%. “70% Chg” indicates a measurement result of a battery where the capacity degradation rate due to continuing degradation is adjusted to 70%. “60% Chg” indicates a measurement result of a battery where the capacity degradation rate due to continuing degradation is adjusted to 60%. The “fresh Chg” indicates a measurement result of a battery (that is, a new product) where the capacity degradation rate is 100%. In addition, “1400 cycle Chg” indicates a measurement result of a battery where 1400 times of charge and discharge are repeated.

With respect to the battery where continuing degradation is applied, the internal resistance value of the battery where a capacity degradation rate is 60% (actually 63.9%) is close to 600 mΩ. When a lower limit voltage is 2.75 V of a prototype of the battery, the capacity degradation rate is 63.9%. The more the lower limit voltage is increased, the usable capacity is reduced more. Therefore, assuming that the lower limit voltage required of the rechargeable battery by the portable device is 3.4 V, the capacity degradation rate is 53.4%. Accordingly, assuming that it is necessary to exchange the rechargeable battery when the capacity degradation rate is 50%, in a case where the internal resistance value is an indicator for determining at the time when exchange of the rechargeable battery is necessary, 600 mΩ corresponds to the time when exchange of the rechargeable battery is necessary. In other words, by setting the threshold value of the internal resistance value to be 600 mΩ, it is possible to recognize the time when the rechargeable battery should be changed due to the continuing degradation.

In addition, the internal resistance value whereby the same capacity degradation rate in the cycle degradation as that in the continuing degradation is obtained is 240 mΩ. It can be found that, via the test result indicated in FIG. 5, the internal resistance value in this case compared to a new battery is not increased much. Therefore, in the case of the cycle degradation, since degradation determination based on only the internal resistance value is difficult, degradation determination based on the capacity degradation rate may be performed. For example, 50% as the capacity degradation rate is a threshold value of the capacity degradation due to the cycle degradation.

An exchange time determination threshold value stating a numerical value of the capacity degradation rate when the exchange of the rechargeable battery is necessary and an exchange time determination threshold value stating a numerical value of the internal resistance value when the exchange of the rechargeable battery is necessary may be set by considering operation time of the portable device and safety of the battery.

For example, in a case where the necessity of exchange of the rechargeable battery is determined based on the capacity degradation rate, since the capacity degradation rate being smaller indicates the more development of the degradation, the calculating processing part 50 determines that, in a case where the calculated capacity degradation rate is greater than the exchange time determination threshold value, exchange of the battery is not necessary. The calculating processing part 50 determines that, in a case where the calculated capacity degradation rate is equal to or less than the exchange time determination threshold value, exchange of the battery is necessary.

By regarding the exchange time determination threshold value as a useable final state and dividing a range of the exchange time determination threshold value into plural parts, it is possible to determine the necessity of the exchange of the rechargeable battery in phases. For example, in a case where 50% as the capacity degradation rate is a threshold value of the capacity degradation, the calculating processing part 50 determines “normal (exchanging is not necessary)” when the calculated capacity degradation rate is between 100% and 70%. When the calculated capacity degradation rate is between 70% and 50%, the calculating processing part 50 determines “caution (exchanging is necessary soon)”. When the calculated capacity degradation rate is between 50% and 40%, the calculating processing part 50 determines “exchanging is necessary”. When the calculated capacity degradation rate is between 40% and 0%, the calculating processing part 50 determines “danger (exchanging is urgently necessary)”.

On the other hand, in a case where the necessity of the exchange of the rechargeable battery is determined based on the internal resistance value, since the internal resistance value being greater indicates more development of the degradation, the calculating processing part 50 determines that, in a case where the calculated capacity degradation rate is smaller than the exchange time determination threshold value, exchange of the battery is not necessary. The calculating processing part 50 determines that, in a case where the calculated capacity degradation rate is equal to or greater than the exchange time determination threshold value, exchange of the battery is necessary.

Similarly, by regarding the exchange time determination threshold value as a useable final state and dividing a range of the exchange time determination threshold value into plural parts, it is possible to determine the necessity of the exchange of the rechargeable battery in phases. For example, in a case where 600 mΩ as the internal resistance value is the exchange time determination threshold value, the calculating processing part 50 determines “normal (exchanging is not necessary)” when the exchange time determination threshold value is between 100 mΩ and 300 mΩ. When the exchange time determination threshold value is between 300 mΩ and 450 mΩ, the calculating processing part 50 determines “caution (exchanging is necessary soon)”. When the exchange time determination threshold value is between 450 mΩ and 600 mΩ, the calculating processing part 50 determines “exchanging is necessary”. When the exchange time determination threshold value is between 600 mΩ and 1000 mΩ, the calculating processing part 50 determines “danger (exchanging is urgently necessary)”.

However, in the actual using environment, since reasons of degradation are various, either the calculated capacity degradation rate or the calculated internal resistance value may first reach the exchange time determination threshold value. Because of this, the calculated capacity degradation rate and the calculated internal resistance value are used. The time when either the calculated capacity degradation rate or the calculated internal resistance value first reaches the exchange time determination threshold value may be determined as a time when the battery is exchanged.

That is, in a case where either the calculated capacity degradation rate or the calculated internal resistance value first reaches the exchange time determination threshold value, the calculating processing part 50 determines that exchange of the battery is necessary. Because of this, even if the calculated internal resistance value does not reach the exchange time determination threshold value because the calculated internal resistance value has not changed much, since the calculated capacity degradation rate reaches the exchange time determination threshold value, it is possible to securely determine the timing when the rechargeable battery is exchanged. In addition, in a case where both the calculated capacity degradation rate and the calculated internal resistance value first reach the exchange time determination threshold value, the calculating processing part 50 may determine that exchange of the battery is necessary. Since the timing when the rechargeable battery is exchanged is determined by two elements, the calculated capacity degradation rate and the calculated internal resistance value in this case compared to the case where the timing when the rechargeable battery is exchanged is determined by a single element, it is possible to prevent an error determination.

In the case where the necessity of the exchange of the rechargeable battery is determined based on the capacity degradation rate and the case where the necessity of the exchange of the rechargeable battery is determined based on the internal resistance value, since the ways of changing of the capacity degradation rate and the internal resistance value are different from each other due to the reason of the degradation, the results of both determinations may not be always the same as each other. For example, it is determined as “caution” in one case and “exchange is necessary” in another case. In this case, the result showing high necessity of replacing the battery may be applied as the result of determination by considering safety.

In other words, the calculating processing part 50 compares a “degree of necessity of exchange based on the capacity degradation rate” determined based on the capacity degradation rate and a “degree of necessity of exchange based on the internal resistance value” determined based on the internal resistance value to each other. The calculating processing part 50 determines the degree of necessity of exchange of the battery based on a higher degree between them. The “degree of necessity of exchange” indicates that the higher the number of the degree is the higher the necessity of exchange is. By applying the “degree of necessity of exchange”, even if numerical values such as the capacity degradation rate and the internal resistance value cannot be simply compared, it is possible to make the necessity of the exchange clear.

More specifically, the calculating processing part 50 determines “degree of necessity of exchange 1 (exchanging is not necessary)” when the calculated capacity degradation rate is between 100% and 70%. When the calculated capacity degradation rate is between 70% and 50%, the calculating processing part 50 determines “degree of necessity of exchange 2 (exchanging is necessary soon)”. When the calculated capacity degradation rate is between 50% and 40%, the calculating processing part 50 determines “degree of necessity of exchange 3 (exchanging is necessary)”. When the calculated capacity degradation rate is between 40% and 0%, the calculating processing part 50 determines “degree of necessity of exchange 4 (exchanging is urgently necessary)”. The calculating processing part 50 determines “degree of necessity of exchange 1 (exchanging is not necessary)” when the exchange time determination threshold value is between 100 mΩ and 300 mΩ. When the exchange time determination threshold value is between 300 mΩ and 450 mΩ, the calculating processing part 50 determines “degree of necessity of exchange 2 (exchanging is necessary soon)”. When the exchange time determination threshold value is between 450 mΩ and 600 mΩ, the calculating processing part 50 determines “degree of necessity of exchange 3 (exchanging is necessary)”. When the exchange time determination threshold value is between 600 mΩ and 1000 mΩ, the calculating processing part 50 determines “degree of necessity of exchange 4 (exchanging is urgently necessary)”. For example, in a case where the degree of necessity of exchange based on the capacity change rate is “2” and the degree of necessity of exchange based on the internal resistance value is “3”, the necessity of the exchange of the rechargeable battery is determined as “3”.

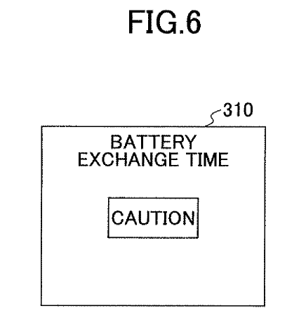

The communication processing part 70 outputs a signal, the signal making information, the information corresponding to a higher degree of necessity of exchange, being displayed on the displaying part 310 which is an information providing part to the user of the portable device 300. For example, if the higher degree of necessity of exchange is “2”, as shown in FIG. 6, a control part such as a microcomputer provided in the portable device 300, performs display control so that “caution”, as the exchange timing of the battery, is displayed on the displaying part 310.

In addition, the calculating processing part 50 calculates a degradation state amount indicating the degradation state of the rechargeable battery, the degradation state amount being where the calculated capacity degradation rate and the internal resistance value are reflected as an element stating the degradation state of the rechargeable battery. It may be determined that the exchange of the rechargeable battery is necessary in a case where the calculated degradation state amount reaches the exchange time determination threshold value.

The degradation state amount may be calculated based on the following formula (4).

Degradation state amount=(1/capacity degradation rate)×weight K1+the internal resistance value×weight K2 (4)

K1 and K2 are zero or positive numbers. By changing the weights, it is possible to change the reflection degree relative to the degradation state amount of the capacity degradation rate and the internal resistance value.

In a case where the necessity of the exchange of the rechargeable battery is determined based on the degradation state amount obtained by the above-mentioned formula (4), the degradation state amount being greater indicates the more development of the degradation. Therefore, the calculating processing part 50 can determine that, in a case where the calculated degradation state amount is smaller than the exchange time determination threshold value, exchange of the battery is not necessary. The calculating processing part 50 determines that, in a case where the calculated degradation state amount is equal to or greater than the exchange time determination threshold value, exchange of the battery is necessary.

Similarly, by regarding the exchange time determination threshold value as a useable final state and dividing a range of the degradation state amount into plural parts, it is possible to determine the necessity of the exchange of the rechargeable battery in phases. For example, in a case where the degradation state amount 100 is the exchange time determination threshold value, the calculating processing part 50 determines “normal (exchanging is not necessary)” when the calculated degradation state amount is between 0 and 60. When the calculated degradation state amount is between 60 and 80, the calculating processing part 50 determines “caution (exchanging is necessary soon)”. When the calculated degradation state amount is between 80 and 100, the calculating processing part 50 determines “exchanging is necessary”. When the calculated degradation state amount is between 100 and 1000, the calculating processing part 50 determines “danger (exchanging is urgently necessary)”. The calculating processing part 50 determines the necessity of exchange of the rechargeable battery based on the degradation state amount so that the more the degradation state amount is the more the necessity of exchange of the rechargeable battery is.

The communication processing part 70 outputs a signal, the signal providing information, the information corresponding to the degradation state amount being displayed on the displaying part 310 which is an information providing part to the user of the portable device 300. For example, if the degradation state amount is “70”, as shown in FIG. 6, a control part such as a microcomputer provided in the portable device 300, performs display control so that “caution”, as the exchange timing of the battery, is displayed on the displaying part 310.

Therefore, according to the above-discussed embodiments, it is possible to securely provide the information of necessity of the exchange of the rechargeable battery regardless of whether the reason of the development of the degradation of the rechargeable battery is the keeping degradation or the cycle degradation. As a result of this, it is possible to improve the usefulness to the user or the safety of the battery.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

For example, as an element for defining the degradation state of the rechargeable battery, at least one of an accumulated value of a charging time of the rechargeable battery and an accumulated value of a reserving time of the rechargeable battery may be reflected in the above-mentioned degradation state amount. Because of this, it is possible to advise the user of the necessity of the exchange of the rechargeable battery. A sum of charging time from a shipping time, a sum of charging time in a low temperature state which is lower than a designated standard time, a sum of charging time in a high temperature state which is higher than the designated standard time, passed days from the shipping time, an integrated time for keeping at a high temperature, an integrated time for keeping at a low temperature, or the like can be used as a concrete element for defining the degradation state of the rechargeable battery.

This patent application is based upon and claims the benefit of priority of the prior Japanese Patent Application No. 2008-233727 filed on Sep. 11, 2008, the entire contents of which are incorporated herein by reference.

### INDUSTRIAL APPLICABILITY

The present invention is applicable to a battery status detecting device, the battery status detecting device configured to detect a status of a rechargeable battery which powers an electronic device, and a battery pack where the battery status detecting device is provided.

### EXPLANATION OF REFERENCE SIGNS

50 calculating processing part
60 memory
70 communication processing part
100A battery pack
200 rechargeable battery
300 portable device
310 display part

1. A battery status detecting device, the battery status detecting device being configured to detect a status of a rechargeable battery which powers an electronic device, the battery status detecting device comprising:
a capacity degradation rate calculating part configured to calculate a capacity degradation rate of the rechargeable battery;
an internal resistance value calculating part configured to calculate an internal resistance value of the rechargeable battery;
a determining part configured to determine necessity of exchange of the rechargeable battery based on the capacity degradation rate calculated by the capacity degradation rate calculating part and the internal resistance value calculated by the internal resistance value calculating part; and
an outputting part configured to output a signal corresponding to a determination result of the determining part,
wherein the determining part determines that the exchange of the rechargeable battery is necessary in a case where one of or both of the capacity degradation rate calculated by the capacity degradation rate calculating part and the internal resistance value calculated by the internal resistance value calculating part reach a value requiring the exchange of the rechargeable battery.

2. The battery status detecting device as claimed in claim 1,
wherein the determining part compares a degree of necessity of the exchange based on the capacity degradation rate calculated by the capacity degradation rate calculating part to the degree of necessity of the exchange based on the internal resistance value calculated by the internal resistance value calculating part, so as to determine the necessity of the exchange of the rechargeable battery based on a higher one of the degrees of the necessity of the exchange.

3. The battery status detecting device as claimed in claim 2,
wherein the output part outputs a signal corresponding to the determination result of the determining part, the signal including information, the information corresponding to a higher degree of necessity of exchange being provided to an information providing part provided in the electronic device.

4. A battery status detecting device, the battery status detecting device being configured to detect a status of a rechargeable battery which powers an electronic device, the battery status detecting device comprising:
a capacity degradation rate calculating part configured to calculate a capacity degradation rate of the rechargeable battery;
an internal resistance value calculating part configured to calculate an internal resistance value of the rechargeable battery;
a determining part configured to determine necessity of exchange of the rechargeable battery based on the capacity degradation rate calculated by the capacity degradation rate calculating part and the internal resistance value calculated by the internal resistance value calculating part; and
an outputting part configured to output a signal corresponding to a determination result of the determining part,
wherein the determining part calculates a degradation state amount, the degradation state amount indicating a degradation state of the rechargeable battery, the degradation state amount being where a capacity degradation rate calculated by the capacity degradation rate calculating part and an internal resistance value calculated by the internal resistance value calculating part are reflected as an element for defining the degradation state of the rechargeable battery, so as to determine that the exchange of the rechargeable battery is necessary in a case where the calculated degradation state amount reaches a value requiring the exchange of the rechargeable battery.

5. The battery status detecting device as claimed in claim 4,
wherein the determining part determines the necessity of the exchange of the rechargeable battery based on the degradation state amount.

6. The battery status detecting device as claimed in claim 5,
wherein the output part outputs a signal corresponding to the determination result of the determining part, the signal including information, the information corresponding to the degradation state amount being provided to an information providing part providing in the electronic device.

7. A battery pack, comprising:
the battery status detecting device as claimed in claim 1; and
a rechargeable battery,
wherein the battery status detecting device and the rechargeable battery are provided in the battery pack.

8. A battery pack, comprising
the battery status detecting device as claimed in claim 4; and
a rechargeable battery,
wherein the battery status detecting device and the rechargeable battery are provided in the battery pack.
